(19) United States
(12) Patent Application Publication
(10) Pub. No.: US 2025/0226011 A1
(43) Pub. Date: Jul. 10, 2025

(54) TEMPERATURE-BASED CHARGE PUMP CONTROL

(71) Applicant: Micron Technology, Inc., Boise, ID (US)

(72) Inventors: Yu-Chung LIEN, San Jose, CA (US); Jun WAN, San Jose, CA (US); Zhenming ZHOU, San Jose, CA (US); John Paul AGLUBAT, Boise, ID (US)

(21) Appl. No.: 18/974,897

(22) Filed: Dec. 10, 2024

Related U.S. Application Data
(60) Provisional application No. 63/617,592, filed on Jan. 4, 2024.

(51) Int. Cl. G11C 5/14; G11C 7/04; G11C 7/22

(52) U.S. Cl. CPC G11C 5/145; G11C 7/04; G11C 7/222; G11C 2207/2281

(57) ABSTRACT

Implementations described herein relate to temperature-based charge pump control. In some implementations, a memory device may comprise one or more components configured to receive a command to perform an operation. The memory device may comprise one or more components configured to detect, responsive to receiving the command, a temperature associated with the memory device. The memory device may comprise one or more components configured to selectively configure, based on the temperature, a clock frequency of a charge pump of the memory device.

### CROSS-REFERENCE TO RELATED APPLICATION

This Patent Application claims priority to U.S. Provisional Patent Application No. 63/617,592, filed on Jan. 4, 2024, and entitled “TEMPERATURE-BASED CHARGE PUMP CONTROL.” The disclosure of the prior Application is considered part of and is incorporated by reference into this Patent Application.

### TECHNICAL FIELD

The present disclosure generally relates to memory devices, memory device operations, and, for example, to temperature-based charge pump control.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of temperature-based charge pump control.

FIG. 2 is a diagram of example components included in a memory device.

FIG. 3 is a diagram of example components included in a memory device.

FIG. 4 is a diagram of an example of an incremental step pulse programming (ISPP) operation.

FIG. 5 is a diagram illustrating an example of single-level cell (SLC), multi-level cell (MLC), triple-level cell (TLC), and quad-level cell (QLC) non-volatile memory.

FIG. 6 is a diagram of an example of temperature-based charge pump control.

FIG. 7 is a diagram of an example associated with a temperature scale and a corresponding lookup table.

FIG. 8 is a flowchart of an example method associated with temperature-based charge pump control.

FIG. 9 is a flowchart of an example method associated with temperature-based charge pump control.

FIG. 10 is a diagram illustrating example systems in which the memory device described herein may be used.

### DETAILED DESCRIPTION

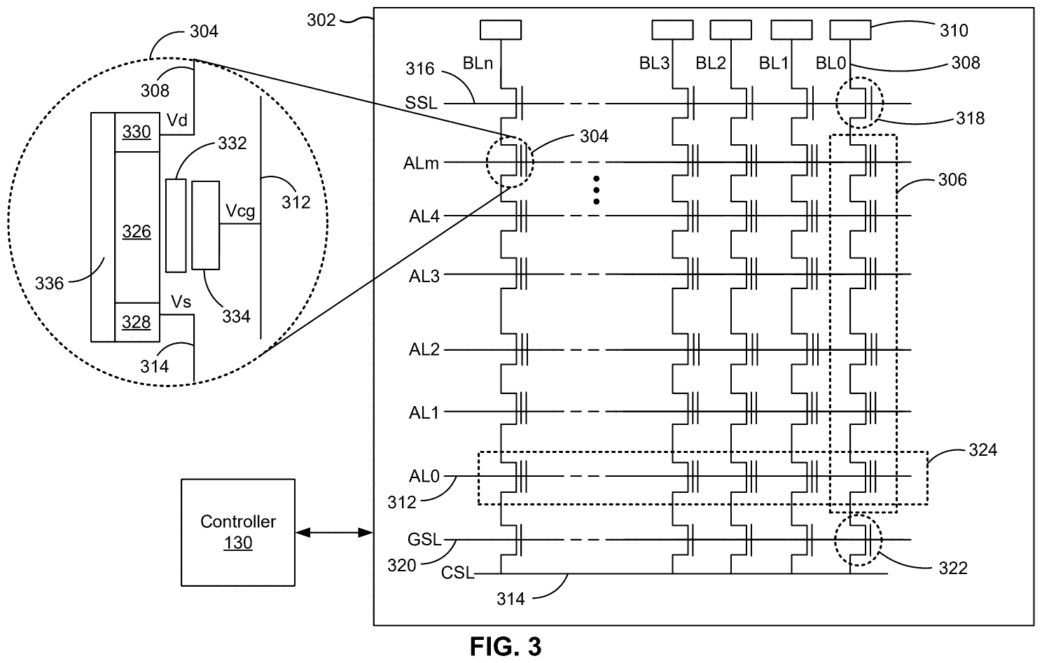

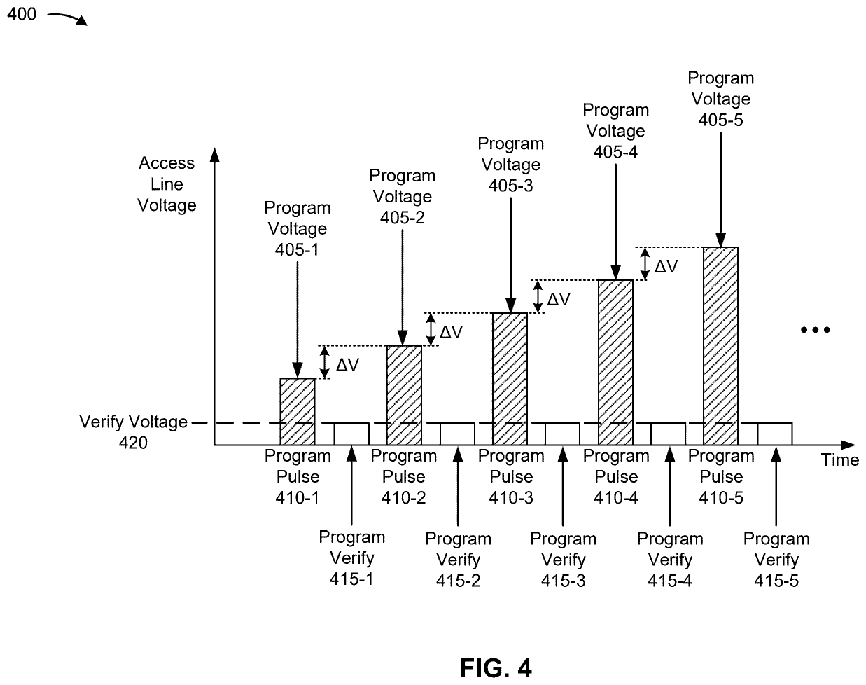

In many cases, a voltage supply (Vcc) is less than a target output voltage (Vout). For example, in a memory device (e.g., in a NAND component), Vcc may be 2.5 volts (V), and various memory operations may involve bias voltages that are greater than 2.5 V. For example, a target pass voltage (Vpass) may be 6.5-7 V, a target program voltage (Vpgm) may be 17-21 V, a target erase voltage (Vera) may be 19 V, or the like. Vpass, Vpgm, and Vera are discussed in greater detail below in connection with FIGS. 3 and 4.

A charge pump is an electronic circuit that can use capacitors to raise or lower voltage. For example, a charge pump can receive Vcc, progressively increase Vcc through a series of stages in the charge pump, and ultimately generate an output voltage (e.g., Vpass, Vpgm, Vera, or the like) that is higher than Vcc. In this manner, charge can be “pumped” through the stages of the charge pump until the output voltage is attained. The rate at which the charge pump increases Vcc to the output voltage (e.g., the working frequency of the charge pump) may be referred to as the “ramp rate” of the charge pump. The output of the charge pump can be coupled to various resistance loading to enable operations on a memory device (e.g., on a NAND array) using Vpass, Vpgm, Vera, or the like.

In some examples, one or more capacitors in a charge pump may be connected to a clock input that changes (e.g., alternates) over time. The rate at which the clock input changes may be referred to as a “clock frequency” of the charge pump. The clock frequency of the clock input may determine the working frequency of the charge pump. For example, alternating capacitors in the charge pump may be connected to complementary clock signals, and by alternating the phase of the clock signals at stages of the charge pump, each stage may alternate between being charged by a previous stage or charging a subsequent stage. In this example, the clock frequency may be the rate at which the clock input alternates.

The clock frequency and the ramp rate may be correlated. For example, a higher clock frequency may correspond to a higher ramp rate, and a lower clock frequency may correspond to a lower ramp rate. In some examples, the clock frequency and/or the ramp rate may be a trim parameter. For instance, a trim parameter for the clock frequency may be referred to as “pclk.” The ramp rate trim parameter may be a word line ramp rate setting.

Decreasing the clock frequency and/or ramp rate may decrease the working frequency of the charge pump, thereby negatively impacting performance of the memory device. However, increasing the clock frequency and/or ramp rate may increase current consumption of the memory device, which can in turn increase the temperature of the memory device. Increased temperatures can cause significant charge loss in the memory device, which can impact data retention. For example, NAND components may be highly sensitive to temperature (e.g., a NAND component may be more vulnerable to high temperatures changes than a central processing unit (CPU), a graphics processing unit (GPU), a solid-state drive (SSD) (e.g., an M.2 SSD), a DRAM, and/or other components that might be found on a motherboard). As a result, for example, a high clock frequency and/or ramp rate for a NAND component in an SSD can lead to poor thermal control of the SSD and impact performance of the NAND component.

Some implementations described herein provide a non-volatile memory controller with a built-in thermal throttling scheme. In some aspects, the memory device may receive a command to perform an operation (e.g., a read operation, a program operation, or the like). In response to receiving the command, the memory device may detect a temperature associated with the memory device. The memory device may identify a clock frequency value or a ramp rate value that corresponds to the temperature and selectively configure a clock frequency or a ramp rate of a charge pump of the memory device based on the clock frequency value, the ramp rate value, and/or the temperature. In some examples, the network device may decrease the clock frequency or the ramp rate if the temperature is above a temperature threshold. In some examples, the network device may increase the clock frequency or the ramp rate if the temperature is below a temperature threshold (which may be the same as or different from the temperature threshold associated with decreasing the clock frequency). In some aspects, the network device may perform the operation.

As a result, the thermal throttling scheme may improve performance of a memory device. For example, if the temperature is above a temperature threshold (e.g., if the memory device is overheating, or close to overheating), then the thermal throttling scheme may decrease the clock frequency or ramp rate of the memory device. Decreasing the clock frequency or ramp rate may lower the temperature of the memory device, thereby improving data retention of the memory device. If the temperature of the memory device is below a temperature threshold (e.g., if the memory device is cool), then the memory device may increase the clock frequency or ramp rate. Increasing the clock frequency or ramp rate may improve the working frequency, and, thus, performance, of the charge pump.

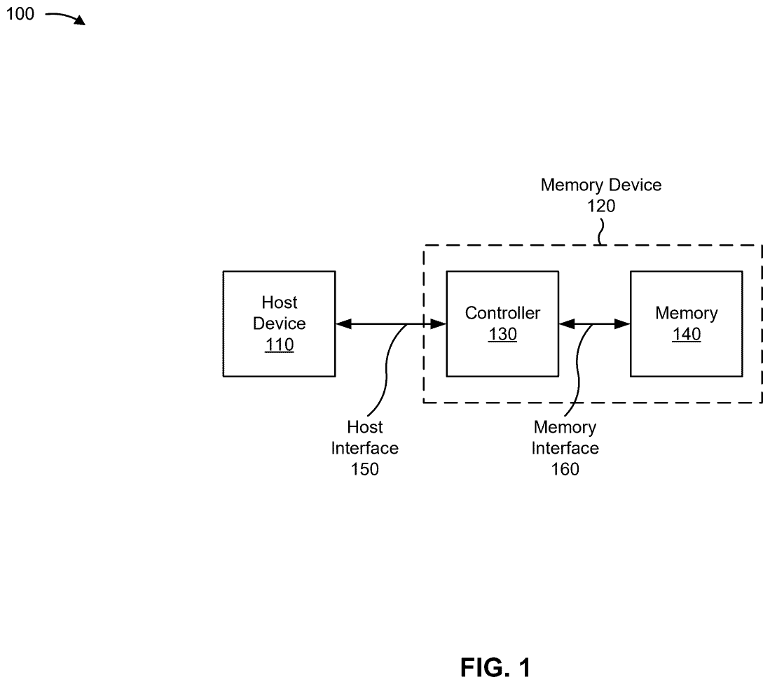

FIG. 1 is a diagram illustrating an example system 100 capable of temperature-based charge pump control. The system 100 may include one or more devices, apparatuses, and/or components for performing operations described herein. For example, the system 100 may include a host device 110 and a memory device 120. The memory device 120 may include a controller 130 and memory 140. The host device 110 may communicate with the memory device 120 (e.g., the controller 130 of the memory device 120) via a host interface 150. The controller 130 and the memory 140 may communicate via a memory interface 160.

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host device 110 may include one or more processors configured to execute instructions and store data in the memory 140. For example, the host device 110 may include a CPU, a GPU, a field-programmable gate array (FPGA), an application-specific integrated circuit (ASIC), and/or another type of processing component.

The memory device 120 may be any electronic device or apparatus configured to store data in memory. In some implementations, the memory device 120 may be an electronic device configured to store data persistently in non-volatile memory. For example, the memory device 120 may be a hard drive, a SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device. In this case, the memory 140 may include non-volatile memory configured to maintain stored data after the memory device 120 is powered off. For example, the memory 140 may include NAND memory or NOR memory. In some implementations, the memory 140 may include volatile memory that requires power to maintain stored data and that loses stored data after the memory device 120 is powered off, such as one or more latches and/or RAM, such as DRAM and/or SRAM. For example, the volatile memory may cache data read from or to be written to non-volatile memory, and/or may cache instructions to be executed by the controller 130.

The controller 130 may be any device configured to communicate with the host device (e.g., via the host interface 150) and the memory 140 (e.g., via the memory interface 160). Additionally, or alternatively, the controller 130 may be configured to control operations of the memory device 120 and/or the memory 140. For example, the controller 130 may include control logic, a memory controller, a system controller, an ASIC, an FPGA, a processor, a microcontroller, and/or one or more processing components. In some implementations, the controller 130 may be a high-level controller, which may communicate directly with the host device 110 and may instruct one or more low-level controllers regarding memory operations to be performed in connection with the memory 140. In some implementations, the controller 130 may be a low-level controller, which may receive instructions regarding memory operations from a high-level controller that interfaces directly with the host device 110. As an example, a high-level controller may be an SSD controller, and a low-level controller may be a non-volatile memory controller (e.g., a NAND controller) or a volatile memory controller (e.g., a DRAM controller). In some implementations, a set of operations described herein as being performed by the controller 130 may be performed by a single controller (e.g., the entire set of operations may be performed by a single high-level controller or a single low-level controller). Alternatively, a set of operations described herein as being performed by the controller 130 may be performed by more than one controller (e.g., a first subset of the operations may be performed by a high-level controller and a second subset of the operations may be performed by a low-level controller).

The host interface 150 enables communication between the host device 110 and the memory device 120. The host interface 150 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, and/or an eMMC interface.

The memory interface 160 enables communication between the memory device 120 and the memory 140. The memory interface 160 may include a non-volatile memory interface (e.g., for communicating with non-volatile memory), such as a NAND interface or a NOR interface. Additionally, or alternatively, the memory interface 160 may include a volatile memory interface (e.g., for communicating with volatile memory), such as a double data rate (DDR) interface.

In some implementations, one or more systems, devices, apparatuses, components, and/or controllers of FIG. 1 may be configured to receive a command to perform an operation; detect, responsive to receiving the command, a temperature associated with the memory device; and selectively configure, based on the temperature, a clock frequency of a charge pump of the memory device.

In some implementations, one or more systems, devices, apparatuses, components, and/or controllers of FIG. 1 may be configured to detect a temperature associated with a memory device; identify a ramp rate value that corresponds to the temperature; and selectively configure a ramp rate of a charge pump of the memory device based on the ramp rate value.

As indicated above, FIG. 1 is provided as an example. Other examples may differ from what is described with regard to FIG. 1.

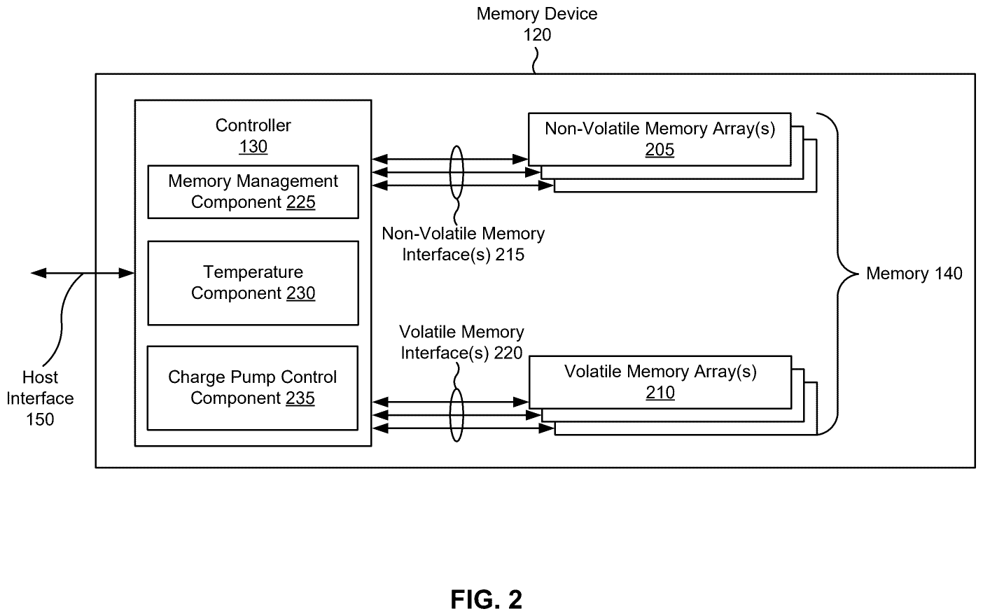

FIG. 2 is a diagram of example components included in a memory device 120. As described above in connection with FIG. 1, the memory device 120 may include a controller 130 and memory 140. As shown in FIG. 2, the memory 140 may include one or more non-volatile memory arrays 205, such as one or more NAND memory arrays and/or one or more NOR memory arrays. Additionally, or alternatively, the memory 140 may include one or more volatile memory arrays 210, such as one or more SRAM arrays and/or one or more DRAM arrays. The controller 130 may transmit signals to and receive signals from a non-volatile memory array 205 using a non-volatile memory interface 215. The controller 130 may transmit signals to and receive signals from a volatile memory array 210 using a volatile memory interface 220.

The controller 130 may control operations of the memory 140, such as by executing one or more instructions. For example, the memory device 120 may store one or more instructions in the memory 140 as firmware, and the controller 130 may execute those one or more instructions. Additionally, or alternatively, the controller 130 may receive one or more instructions from the host device 110 via the host interface 150, and may execute those one or more instructions. In some implementations, a non-transitory computer-readable medium (e.g., volatile memory and/or non-volatile memory) may store a set of instructions (e.g., one or more instructions or code) for execution by the controller 130. The controller 130 may execute the set of instructions to perform one or more operations or methods described herein. In some implementations, execution of the set of instructions, by the controller 130, causes the controller 130 and/or the memory device 120 to perform one or more operations or methods described herein. In some implementations, hardwired circuitry is used instead of or in combination with the one or more instructions to perform one or more operations or methods described herein. Additionally, or alternatively, the controller 130 and/or one or more components of the memory device 120 may be configured to perform one or more operations or methods described herein. An instruction is sometimes called a “command.”

For example, the controller 130 may transmit signals to and/or receive signals from the memory 140 based on the one or more instructions, such as to transfer data to (e.g., write or program), to transfer data from (e.g., read), and/or to erase all or a portion of the memory 140 (e.g., one or more memory cells, pages, sub-blocks, blocks, or planes of the memory 140). Additionally, or alternatively, the controller 130 may be configured to control access to the memory 140 and/or to provide a translation layer between the host device 110 and the memory 140 (e.g., for mapping logical addresses to physical addresses of a memory array). In some implementations, the controller 130 may translate a host interface command (e.g., a command received from the host device 110) into a memory interface command (e.g., a command for performing an operation on a memory array).

As shown in FIG. 2, the controller 130 may include a memory management component 225, a temperature component 230, and/or a charge pump control component 235. In some implementations, one or more of these components are implemented as one or more instructions (e.g., firmware) executed by the controller 130. Alternatively, one or more of these components may be implemented as dedicated integrated circuits distinct from the controller 130.

The memory management component 225 may be configured to manage performance of the memory device 120. For example, the memory management component 225 may perform wear leveling, bad block management, block retirement, read disturb management, and/or other memory management operations. In some implementations, the memory device 120 may store (e.g., in memory 140) one or more memory management tables. A memory management table may store information that may be used by or updated by the memory management component 225, such as information regarding memory block age, memory block erase count, and/or error information associated with a memory partition (e.g., a memory cell, a row of memory, a block of memory, or the like).

The temperature component 230 may be configured to monitor and/or identify a temperature associated with the memory 140, such as an internal operating temperature of the memory device 120, an ambient temperature in which the memory device 120 is operating, a temperature of one or more memory components of the memory device 120, or the like. In some implementations, the temperature component 230 may include or may be associated with a thermometer to measure a temperature associated with the memory 140.

The charge pump control component 235 may be configured to selectively configure a charge pump parameter based on the temperature. For example, the charge pump control component 235 may adjust (e.g., increase or decrease) a clock frequency and/or a ramp rate of a charge pump of the memory device 120 based on the temperature. The charge pump control component 235 may use a lookup table to determine whether and/or how much to increase or decrease the clock frequency and/or the ramp rate of the charge pump.

One or more devices or components shown in FIG. 2 may be configured to perform operations described herein, such as one or more operations and/or methods described in connection with FIGS. 3-10. For example, the controller 130, the memory management component 225, the temperature component 230, and/or the charge pump control component 235 may be configured to perform one or more operations and/or methods for the memory device 120.

The number and arrangement of components shown in FIG. 2 are provided as an example. In practice, there may be additional components, fewer components, different components, or differently arranged components than those shown in FIG. 2. Furthermore, two or more components shown in FIG. 2 may be implemented within a single component, or a single component shown in FIG. 2 may be implemented as multiple, distributed components. Additionally, or alternatively, a set of components (e.g., one or more components) shown in FIG. 2 may perform one or more operations described as being performed by another set of components shown in FIG. 2.

FIG. 3 is a diagram of example components included in a memory device 120. As described above in connection with FIG. 1, the memory device 120 may include a controller 130 and memory 140. As shown in FIG. 3, the memory 140 may include a memory array 302, which may correspond to a non-volatile memory array 210 described above in connection with FIG. 2.

In FIG. 3, the memory array 302 is a NAND memory array. However, in some implementations, the memory array 302 may be another type of memory array, such as a NOR memory array, a RRAM memory array, a MRAM memory array, a FeRAM memory array, a spin-transfer torque RAM (STT-RAM) memory array, or the like. In some implementations, the memory array 302 is part of a three-dimensional stack of memory arrays, such as 3D NAND flash memory, 3D NOR flash memory, or the like.

The memory array 302 includes multiple memory cells 304. A memory cell 304 may store an analog value, such as an electrical voltage or an electrical charge, that represents a data state (e.g., a digital value). The analog value and corresponding data state depend on a quantity of electrons trapped or present within a region of the memory cell 304 (e.g., in a charge trap, such as a floating gate), as described below.

A NAND string 306 (sometimes called a string) may include multiple memory cells 304 connected in series. A NAND string 306 is coupled to a bit line 308 (sometimes called a digit line or a column line, and shown as BL0-BLn). Data can be read from or written to the memory cells 304 of a NAND string 306 via a corresponding bit line 308 using one or more input/output (I/O) components 310 (e.g., an I/O circuit, an I/O bus, a page buffer, and/or a sensing component, such as a sense amplifier). Memory cells 304 of different NAND strings 306 (e.g., one memory cell 304 per NAND string 306) may be coupled with one another via access lines 312 (sometimes called word lines or row lines, and shown as AL0-ALm) that select which row (or rows) of memory cells 304 is affected by a memory operation (e.g., a read operation or a write operation).

A NAND string 306 may be connected to a bit line 308 at one end and a common source line (CSL) 314 at the other end. A string select line (SSL) 316 may be used to control respective string select transistors 318. A string select transistor 318 selectively couples a NAND string 306 to a corresponding bit line 308. A ground select line (GSL) 320 may be used to control respective ground select transistors 322. A ground select transistor 322 selectively couples a NAND string 306 to the common source line 314.

A “page” of memory (or “a memory page”) may refer to a group of memory cells 304 connected to the same access line 312, as shown by reference number 324. In some implementations (e.g., for SLCs), the memory cells 304 connected to an access line 312 may be associated with a single page of memory. In some implementations (e.g., for multi-level cells), the memory cells 304 connected to an access line 312 may be associated with multiple pages of memory, where each page represents one bit stored in each of the memory cells 304 (e.g., a lower page that represents a first bit stored in each memory cell 304 and an upper page that represents a second bit stored in each memory cell 304). In NAND memory, a page is the smallest physically addressable data unit for a write operation (sometimes called a program operation).

In some implementations, a memory cell 304 is a floating-gate transistor memory cell. In this case, the memory cell 304 may include a channel 326, a source region 328, a drain region 330, a floating gate 332, and a control gate 334. The source region 328, the drain region 330, and the channel 326 may be on a substrate 336 (e.g., a semiconductor substrate). The memory device 120 may store a data state in the memory cell 304 by charging the floating gate 332 to a particular voltage associated with the data state and/or to a voltage that is within a range of voltages associated with the data state. This results in a predefined amount of current flowing through the channel 326 (e.g., from the source region 328 to the drain region 330) when a specified read voltage is applied to the control gate 334 (e.g., by a corresponding access line 312 connected to the control gate 334). Although not shown, a tunnel oxide layer (or tunnel dielectric layer) may be interposed between the floating gate 332 and the channel 326, and a gate oxide layer (e.g., a gate dielectric layer) may be interposed between the floating gate 332 and the control gate 334. As shown, a drain voltage Vd may be supplied from a bit line 308, a control gate voltage Veg may be supplied from an access line 312, and a source voltage Vs may be supplied via the common source line 314 (which, in some implementations, is a ground voltage).

To write or program the memory cell 304, Fowler-Nordheim tunneling may be used. For example, a strong positive voltage potential may be created between the control gate 334 and the channel 326 (e.g., by applying a large positive voltage to the control gate 334 via a corresponding access line 312) while current is flowing through the channel 326 (e.g., from the common source line 314 to the bit line 308, or vice versa). The strong positive voltage at the control gate 334 causes electrons within the channel 326 to tunnel through the tunnel oxide layer and be trapped in the floating gate 332. These negatively charged electrons then act as an electron barrier between the control gate 334 and the channel 326 that increases the threshold voltage of the memory cell 304. The threshold voltage is a voltage required at the control gate 334 to cause current (e.g., a threshold amount of current) to flow through the channel 326. Fowler-Nordheim tunneling is an example technique for storing a charge in the floating gate, and other techniques, such as channel hot electron injection, may be used.

To read the memory cell 304, a read voltage may be applied to the control gate 334 (e.g., via a corresponding access line 312), and an I/O component 310 (e.g., a sense amplifier) may determine the data state of the memory cell 304 based on whether current passes through the memory cell 304 (e.g., the channel 326) due to the applied voltage. A pass voltage may be applied to all memory cells 304 (other than the memory cell 304 being read) in the same NAND string 306 as the memory cell 304 being read. For example, the pass voltage may be applied on each access line 312 other than the access line 312 of the memory cell 304 being read (e.g., where the read voltage is applied). The pass voltage is higher than the highest read voltage associated with any memory cell data states so that all of the other memory cells 304 in the NAND string 306 conduct, and the I/O component 310 can detect a data state of the memory cell 304 being read by sensing current (or lack thereof) on a corresponding bit line 308. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 334 to distinguish between the three or more data states and determine a data state of the memory cell 304.

To erase the memory cell 304, a strong negative voltage potential (e.g., an erase voltage) may be created between the control gate 334 and the channel 326 (e.g., by applying a large negative voltage to the control gate 334 via a corresponding access line 312). The strong negative voltage at the control gate 334 causes trapped electrons in the floating gate 332 to tunnel back across the oxide layer from the floating gate 332 to the channel 326 and to flow between the common source line 314 and the bit line 308. This removes the electron barrier between the control gate 334 and the channel 326 and decreases the threshold voltage of the memory cell 304 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some implementations, a block may be divided into multiple sub-blocks. A sub-block is a portion of a block and may include a subset of pages of the block and/or a subset of memory cells of the block.

As indicated above, FIG. 3 is provided as an example. Other examples may differ from what is described with regard to FIG. 3.

FIG. 4 is a diagram of an example 400 of an ISPP operation. An ISPP operation may be used to program (i.e., write to) memory cells. In an ISPP operation, multiple program voltages 405 (sometimes called write voltages) are iteratively applied to a selected access line associated with a page to be programmed. The program voltages 405 increase in magnitude over time (shown as an increase of ΔV), such that an increasing voltage differential is applied to control gates of memory cells to be programmed. Each application of a program voltage 405 may be called a program pulse 410.

For example, a first program voltage 405-1 of a first program pulse 410-1 of an ISPP operation may be the lowest program voltage applied during the ISPP operation. A second program voltage 405-2 of a second program pulse 410-2 of the ISPP operation may be greater than the first program voltage 405-1 (e.g., by a pulse step voltage, shown as ΔV), a third program voltage 405-3 of a third program pulse 410-3 of the ISPP operation may be greater than the second program voltage 405-2 (e.g., by ΔV), and so on. Although the pulse step voltages are shown as being uniform between consecutive pulses, in some implementations, a non-uniform pulse step may be used.

In the ISPP operation, a program verify operation 415 (sometimes called a write verify operation) may be performed after each program pulse 410. The program verify operation 415 includes applying a verify voltage 420 to the selected access line to read the memory cells on the selected access line and determine whether those memory cells have been programmed (e.g., whether a program pulse 410 preceding the program verify operation 415 successfully programmed the memory cells). The program verify operation 415 may be used to differentiate between a set of “pass” memory cells that have been programmed to a desired state and a set of “fail” memory cells that have not been programmed to the desired state based on whether the memory cells conduct when the verify voltage 420 is applied. For example, the verify voltage 420 may be a read voltage corresponding to the desired state.

In some implementations, after a memory cell is identified as a pass memory cell that stores a desired state, that memory cell may be inhibited from further programming by subsequent program pulses 410 (e.g., program pulses 410, of the ISPP operation, that occur after the program verify operation 415 that verified the pass memory cell). For example, the memory device may apply an inhibit voltage (e.g., a positive voltage) to the bit line of the pass memory cell so that a program voltage 405 applied to the control gate of the pass memory cell does not create sufficient voltage differential to draw additional electrons into the floating gate. As an example, if a memory cell is identified as a pass memory cell based on performing the illustrated program verify operation 415-3, then that memory cell may be inhibited from programming during the program pulses 410-4 and 410-5. By inhibiting pass memory cells from further programming, the desired state can be locked into a pass memory cell and the endurance (e.g., a lifespan) of the pass memory cell may be extended by preventing incrementally greater program voltages 405 from degrading the pass memory cell.

The ISPP operation may continue until a condition is satisfied, such as all of the selected memory cells being programmed in the desired state, a threshold quantity or percentage of memory cells being programmed in the desired state, a threshold quantity of program pulses 410 being applied, or a threshold program voltage 405 being reached. Although the ISPP operation shown in FIG. 4 includes five program pulses 410 and five program verify operations 415, the ISPP operation may include a different quantity of program pulses 410 and/or program verify operations 415 in some implementations.

As indicated above, FIG. 4 is provided as an example. Other examples may differ from what is described with regard to FIG. 4.

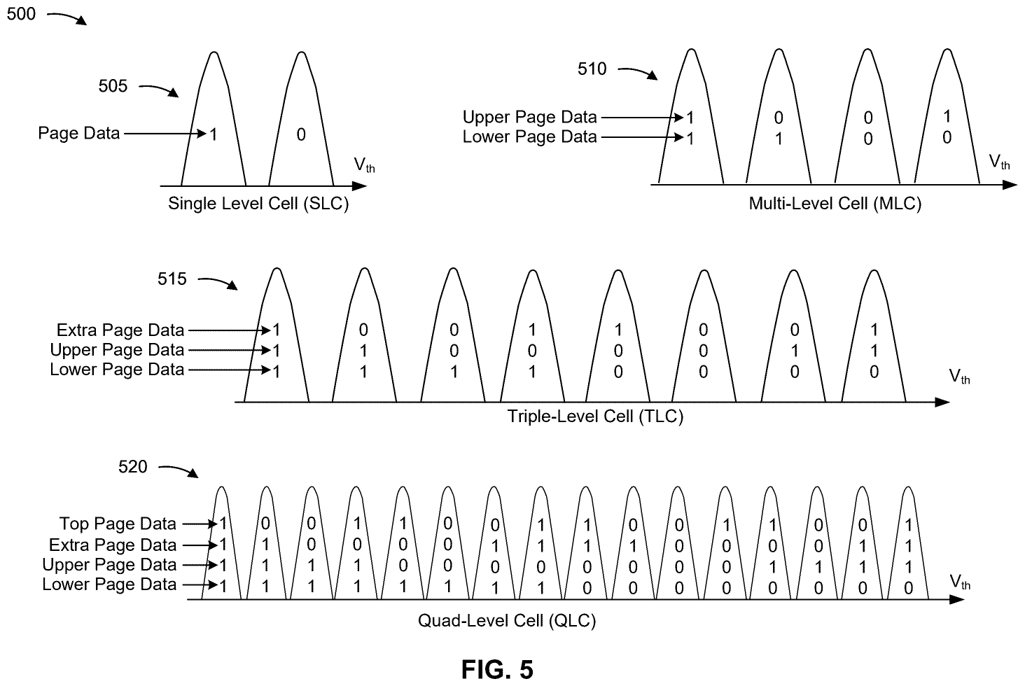

FIG. 5 is a diagram illustrating an example 500 of SLC, MLC, TLC, and QLC non-volatile memory. One or more of these memory types may be used by a memory device described herein.

More particularly, a non-volatile memory cell, such as a NAND cell, may be categorized as an SLC, an MLC, a TLC, or a QLC, among other examples. As shown by reference number 505, an SLC stores a single binary bit per memory cell, and thus may store either binary 1 or binary 0. In an SLC, the stored bit is sometimes referred to as the page data of the memory cell. When writing to an SLC, the cell may be charged to a threshold voltage (Vth) falling within the distribution of the curve labeled with page data “1” when the memory cell is to store binary 1 (or else may include no charge when the memory cell is to store binary 1), and may be charged to a threshold voltage falling within the distribution of the curve labeled with page data “0” when the memory cell is to store binary 0.

Unlike an SLC, which only stores a single bit, an MLC, a TLC, and a QLC may store multiple bits per memory cell. More particularly, as shown by reference number 510, an MLC stores two binary bits per memory cell, and thus is capable of storing binary 11, binary 01, binary 00, or binary 10 according to a level of a charged stored in the MLC. In an MLC, a first stored bit is sometimes referred to as the cell's upper page data, and the second stored bit is sometimes referred to as the cell's lower page data. When writing to an MLC, the cell may be charged to a threshold voltage falling within the distribution of the curve labeled with page data “11” when the memory cell is to store binary 11, the cell may be charged to a threshold voltage falling within the distribution of the curve labeled with page data “01” when the memory cell is to store binary a 01, the cell may be charged to a threshold voltage falling within the distribution of the curve labeled with page data “00” when the memory cell is to store binary 00, and the cell may be charged to a threshold voltage falling within the distribution of the curve labeled with page data “10” when the memory cell is to store binary 10. In some implementations, an MLC stores binary 11 when the MLC's charge is approximately 25% full, the MLC stores binary 01 when the MLC's charge is approximately 50% full, the MLC stores binary 00 when the MLC's charge is approximately 75%, and the MLC stores binary 10 when the MLC's charge is approximately 100% full.

In a similar manner, and as shown by reference number 515, a TLC stores three binary bits per memory cell, and thus a TLC is capable of storing binary 111, binary 011, binary 001, binary 101, binary 100, binary 000, binary 010, or binary 110. For a TLC, the first, second, and third stored bits are sometimes referred to as the cell's “extra page data,” the cell's “upper page data,” and the cell's “lower page data,” respectively. Moreover, as shown by reference number 520, a QLC stores four binary bits per memory cell, and thus is capable of storing binary 1111, binary 0111, binary 0011, binary 1011, binary 1001, binary 0001, binary 0101, binary 1101, binary 1100, binary 0100, binary 0000, binary 1000, binary 1010, binary 0010, binary 0110, or binary 1110. For a QLC, the first, second, third, and fourth bits are sometimes referred to as the cell's “top page data,” the cell's “extra page data,” the cell's “upper page data,” and the cell's “lower page data,” respectively. More broadly, for an n-bit memory cell, the threshold voltage of the cell may be programmed to 2ⁿ separate states, with each state corresponding to a non-overlapping threshold distribution, as shown for the various memory cells in FIG. 5.

To read the data stored in a memory cell, such as an SLC, an MLC, a TLC, a QLC, or another type of memory cell, a memory device (or a component thereof) may sense a voltage associated with the stored charge on the memory cell (e.g., may sense a Vth associated with the cell) and determine a corresponding binary number associated with that voltage.

As indicated above, FIG. 5 is provided as an example. Other examples may differ from what is described with regard to FIG. 5.

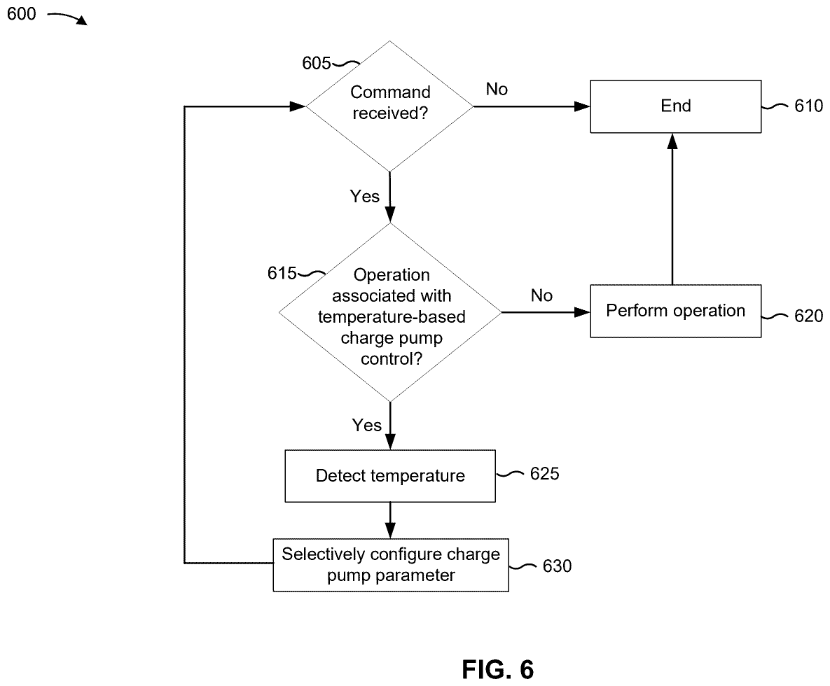

FIG. 6 is a diagram of an example 600 of temperature-based charge pump control. The operations described in connection with FIG. 6 may be performed by the memory device 120 and/or one or more components of the memory device 120, such as the controller 130 and/or one or more components of the controller 130. In some aspects, the memory device 120 may be a non-volatile memory device. For example, the non-volatile memory device may be a NAND memory device or any other suitable type of non-volatile memory device, examples of which are provided elsewhere herein.

As shown by reference number 605, the memory device 120 (e.g., the controller 130) may determine whether the memory device 120 has received a command to perform an operation. In some examples, the memory device 120 may not receive a command. As shown by reference number 610, if the memory device 120 has not received a command, then the example 600 may end.

In some aspects, the host device 110 may transmit, and the memory device 120 (e.g., the controller 130) may receive, a command to perform an operation. The command may be a command to perform an operation on a memory array. For example, the operation may be a read operation, a program operation, or the like.

As shown by reference number 615, the memory device 120 may determine whether the operation is associated with temperature-based charge pump control. An operation may be associated temperature-based charge pump control in that the memory device 120 may be configured to perform temperature-based charge pump control for the operation. For example, temperature-based charge pump control may support certain operations. For example, commands to perform certain NAND array operations may be associated with temperature-based charge pump control.

As shown by reference number 620, if the memory device 120 determines that the operation is not associated with temperature-based charge pump control, then the memory device 120 may perform the operation, and, as shown by reference number 610, the example 600 may end.

As shown by reference number 625, the memory device 120 may detect a temperature associated with the memory device 120. For example, the memory device 120 may detect a temperature associated with the memory device 120 if the memory device 120 determines that the operation is associated with temperature-based charge pump control. The memory device 120 may detect the temperature responsive to receiving the command (e.g., responsive to determining that the operation is associated with temperature-based charge pump control). The temperature may be associated with the memory device 120 in that the temperature may be an internal operating temperature of the memory device 120, an ambient temperature in which the memory device 120 is operating, a temperature of one or more components of the memory device 120, or the like.

In some aspects, the memory device 120 may identify a charge pump value that corresponds to the temperature. The charge pump value may be a ramp rate value, a clock frequency value, or the like. In some aspects, the memory device 120 may identify the charge pump value using a lookup table. For example, the lookup table may indicate multiple temperature ranges and, for each temperature range of the multiple temperature ranges, a corresponding charge pump value. For example, the memory device 120 may identify the charge pump value that corresponds to the temperature range that contains the temperature.

In some aspects, the memory device 120 may identify the charge pump value based on a quantity of bits associated with a memory cell. For example, the command may be to read from, or write to, the memory cell. The quantity of bits may be associated with the memory cell in that the quantity of bits may be a maximum quantity of bits (e.g., binary bits) that the memory cell can store. In some aspects, the memory cell may be an SLC, and the quantity of bits may be one. In some aspects, the memory cell may be an MLC, and the quantity of bits may be two. In some aspects, the memory cell may be a TLC, and the quantity of bits may be three. In some aspects, the memory cell may be an QLC, and the quantity of bits may be four. Thus, the command may be to perform an SLC read operation (e.g., an SLC page read operation), an MLC read operation, a TLC read operation, a QLC read operation, or the like.

As shown by reference number 630, the memory device 120 may selectively configure a charge pump parameter of the memory device. For example, the charge pump parameter may be a clock frequency of the charge pump of the memory device 120 and/or a ramp rate of the charge pump of the memory device 120. The memory device 120 may selectively configure the charge pump parameter based on the temperature and/or the charge pump value. For example, the memory device 120 may selectively set a value of the charge pump parameter to the charge pump value. For example, the memory device 120 may configure the charge pump to operate at the clock frequency value and/or the ramp rate value.

The memory device 120 may selectively configure the charge pump parameter in that the memory device 120 may or may not, based on the temperature and/or the charge pump value, configure the charge pump parameter. In some examples, the memory device 120 may configure the charge pump parameter if the value of the charge pump parameter is different than the charge pump value (e.g., if the charge pump parameter was previous configured with a different value). In some examples, the memory device 120 may refrain from configuring the charge pump parameter with the charge pump value if the value of the charge pump parameter is the same as the charge pump value (e.g., if the charge pump parameter was previous configured with the same value).

In some examples, the memory device 120 may selectively configure the charge pump parameter using the lookup table. For example, the memory device 120 may selectively configure the charge pump parameter with the charge pump value that was identified in the lookup table. In some examples, the memory device 120 may selectively configure the charge pump value based on the quantity of bits associated with the memory cell. For example, the memory device 120 may selectively configure the charge pump parameter with the charge pump value that was identified based on the quantity of bits associated with the memory cell.

In some examples, the charge pump parameter may be a shared trim parameter that is common to read operations and program operations. Additionally, or alternatively, the charge pump parameter may be a shared trim parameter that is common to SLC and TLC (and/or MLC and/or QLC). Additionally, or alternatively, the charge pump parameter may be a separated for read operations and program operations. Additionally, or alternatively, the charge pump parameter may be a separated for SLC and TLC (and/or MLC and/or QLC). For example, trim parameter separation may be applied to SLC read operations because decreasing the charge pump parameter may dissipate power more efficiently for an SLC read operation than for other types of operations.

The memory device 120 may perform (e.g., execute) the operation before detecting the temperature or after selectively configuring the charge pump parameter. In some aspects, the memory device 120 may perform the operation before detecting the temperature. For example, the memory device 120 may receive the command to perform the operation, perform the operation, and then detect the temperature and selectively configure the charge pump parameter. In some aspects, the memory device 120 may perform the operation after selectively configuring the charge pump parameter. For example, the memory device 120 may receive the command to perform the operation, detect the temperature, selectively configure the charge pump parameter, and then perform the operation. The memory device 120 may perform the operation at any suitable time, such as after detecting the temperature and before selectively configuring the charge pump parameter, and/or concurrently with any other suitable operations described herein.

Returning to reference number 605, after selectively configuring the charge pump parameter, the memory device 120 may determine whether any additional commands have been received. If an additional command has been received, then the memory device 120 may proceed as described above in connection with reference numbers 615-630. If no additional command has been received, then example 600 may end as shown by reference number 610.

As indicated above, FIG. 6 is provided as an example. Other examples may differ from what is described with regard to FIG. 6.

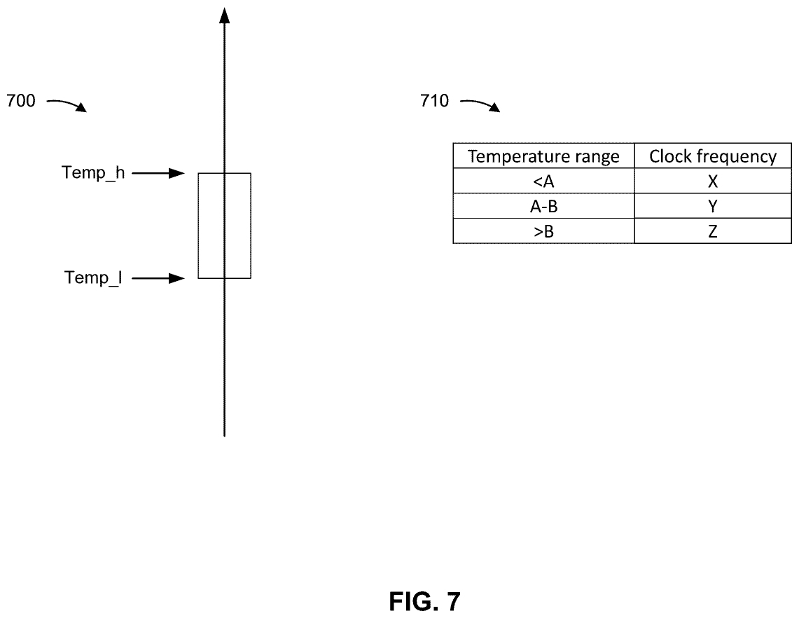

FIG. 7 is a diagram of an example associated with a temperature scale 700 and a corresponding lookup table 710.

The temperature scale 700 includes a temperature range defined by a lower temperature boundary (“Temp_l”) and an upper temperature boundary (“Temp_h”). In some examples, a host device (e.g., host device 110) may configure Temp_l and Temp_h (e.g., the temperature range may be user-specified).

In some examples, a thermal alert feature may enable a memory device (e.g., a controller of the memory device, such as controller 130) to alert the host device when the memory device is operating outside the temperature range. For example, the thermal alert feature may provide the host device with information regarding a temperature associated with the memory device by updating status register values after every valid array operation (e.g., after operations associated with temperature-based charge pump control). The thermal alert feature may reduce overhead by avoiding host device polling for the temperature. Additionally, or alternatively, by sampling temperature information when a valid array operation (e.g., a given read operation) occurs, the thermal alert feature may reduce delay associated with monitoring the temperature.

The lookup table 710 includes a plurality of temperature ranges and corresponding clock frequencies. In some examples, the memory device may perform a valid array operation with the thermal alert feature enabled and, based on the output of the thermal alert feature, set the clock frequency of a charge pump of the memory device using the lookup table.

For example, the lookup table 710 includes three temperature ranges defined by Temp_l (e.g., A) and Temp_h (e.g., B). If the thermal alert feature outputs a temperature that is less than Temp_l, then the memory device may set the clock frequency to correspond to X ns (e.g., the clock input may alternate once every X ns). If the thermal alert feature outputs a temperature between Temp_l and Temp_h, then the memory device may set the clock frequency to correspond to Y ns. If the thermal alert feature outputs a temperature greater than Temp_h, then the memory device may set the clock frequency to correspond to Z ns. A, B, X, Y, and Z may be any suitable values.

For example, if the clock frequency is currently set to correspond to Y ns or Z ns, and the thermal alert feature outputs a temperature less than Temp_l, then the memory device may decrease the clock frequency to correspond to X ns. Or, if the clock frequency is currently set to correspond to X ns or correspond to Y ns, and the thermal alert feature outputs a temperature greater than Temp_h, then the memory device may increase the clock frequency to correspond to Z ns. Thus, the clock frequency of the charge pump may be a temperature-dependent trim setting that is adjustable by outputting the temperature of the memory device and checking (e.g., by a system, such as the memory device) the lookup table.

Although in this example the lookup table 710 includes three temperature ranges, a lookup table in accordance with implementations provided herein may include any suitable quantity of entries (e.g., temperature ranges) that contain any suitable temperature ranges and/or clock frequency values. For example, such a lookup table may define any suitable temperature ranges and/or frequency clock values at any suitable level(s) of granularity. For example, the temperature ranges may be defined by any suitable minimum and/or maximum temperatures, and any suitable frequency clock values may correspond to the temperature ranges.

As indicated above, FIG. 7 is provided as an example. Other examples may differ from what is described with regard to FIG. 7.

Selectively configuring the clock frequency or ramp rate based on the temperature may enable the memory device 120 (e.g., the controller 130) to improve the performance of the memory device 120. In some examples, the memory device 120 may lower the clock frequency or ramp rate, which may lower the temperature of the memory device 120, which may in turn reduce power dissipation, with negligible tread penalty and/or little or no impact on reliability, thereby mitigating overheating and improving data retention. For example, lowering the clock frequency or ramp rate may alleviate heat dissipation issues on a package (e.g., drive) level. In some examples, the memory device 120 may increase the clock frequency or ramp rate (e.g., after the temperature of the memory device 120 drops), thereby improving the working frequency, and, thus, performance, of the charge pump.

Performing the operation before detecting the temperature may enable the memory device 120 to reduce delay associated with performing the operation. Performing the operation after selectively configuring the clock frequency may enable the memory device 120 to reduce delay associated with selectively configuring the temperature of the memory device 120.

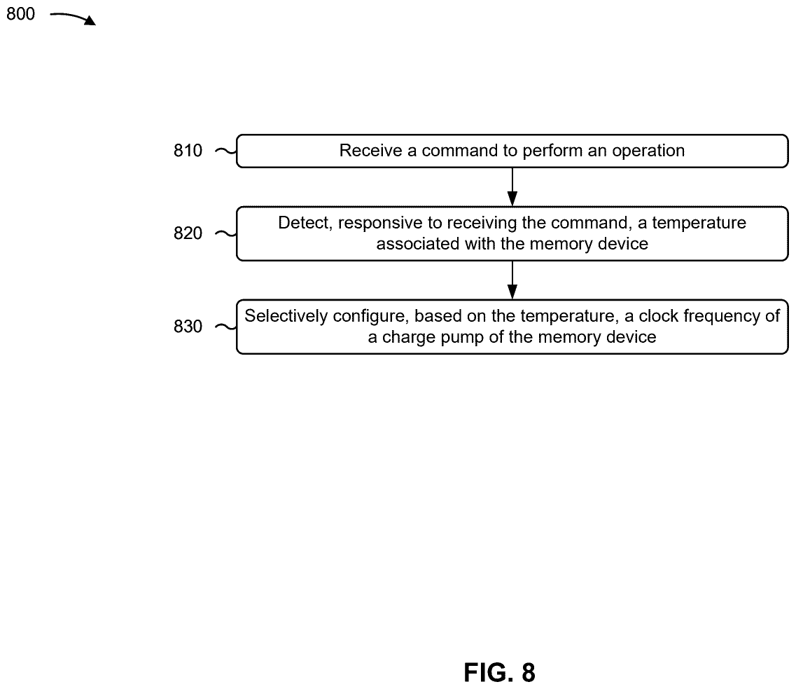

FIG. 8 is a flowchart of an example method 800 associated with temperature-based charge pump control. In some implementations, a memory device (e.g., the memory device 120) may perform or may be configured to perform the method 800. In some implementations, another device or a group of devices separate from or including the memory device (e.g., the system 100) may perform or may be configured to perform the method 800. Additionally, or alternatively, one or more components of the memory device (e.g., the controller 130, the memory management component 225, temperature component 230, and/or charge pump control component 235) may perform or may be configured to perform the method 800. Thus, means for performing the method 800 may include the memory device and/or one or more components of the memory device. Additionally, or alternatively, a non-transitory computer-readable medium may store one or more instructions that, when executed by the memory device (e.g., the controller 130 of the memory device 120), cause the memory device to perform the method 800.

As shown in FIG. 8, the method 800 may include receiving a command to perform an operation (block 810). As further shown in FIG. 8, the method 800 may include detecting, responsive to receiving the command, a temperature associated with the memory device (block 820). As further shown in FIG. 8, the method 800 may include selectively configuring, based on the temperature, a clock frequency of a charge pump of the memory device (block 830).

The method 800 may include additional aspects, such as any single aspect or any combination of aspects described below and/or described in connection with one or more other methods or operations described elsewhere herein.

In a first aspect, the operation is a read operation.

In a second aspect, alone or in combination with the first aspect, selectively configuring the clock frequency includes selectively configuring the clock frequency based on a quantity of bits associated with a memory cell.

In a third aspect, alone or in combination with one or more of the first and second aspects, the memory cell is an SLC.

In a fourth aspect, alone or in combination with one or more of the first through third aspects, the operation is a program operation.

In a fifth aspect, alone or in combination with one or more of the first through fourth aspects, selectively configuring the clock frequency includes selectively configuring the clock frequency using a lookup table.

In a sixth aspect, alone or in combination with one or more of the first through fifth aspects, the lookup table indicates multiple temperature ranges and, for each temperature range of the multiple temperature ranges, a corresponding clock frequency value.

In a seventh aspect, alone or in combination with one or more of the first through sixth aspects, the method 800 includes performing the operation before detecting the temperature.

In an eighth aspect, alone or in combination with one or more of the first through seventh aspects, the method 800 includes performing the operation after selectively configuring the clock frequency.

In a ninth aspect, alone or in combination with one or more of the first through eighth aspects, the memory device is a non-volatile memory device.

In a tenth aspect, alone or in combination with one or more of the first through ninth aspects, the non-volatile memory device is a NAND memory device.

Although FIG. 8 shows example blocks of a method 800, in some implementations, the method 800 may include additional blocks, fewer blocks, different blocks, or differently arranged blocks than those depicted in FIG. 8. Additionally, or alternatively, two or more of the blocks of the method 800 may be performed in parallel. The method 800 is an example of one method that may be performed by one or more devices described herein. These one or more devices may perform or may be configured to perform one or more other methods based on operations described herein.

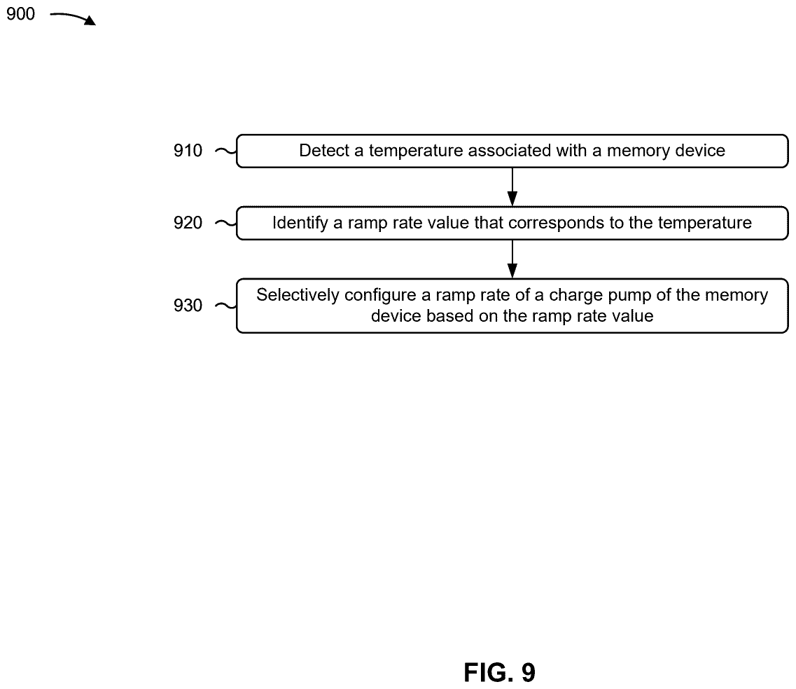

FIG. 9 is a flowchart of an example method 900 associated with temperature-based charge pump control. In some implementations, a memory device (e.g., the memory device 120) may perform or may be configured to perform the method 900. In some implementations, another device or a group of devices separate from or including the memory device (e.g., the system 100) may perform or may be configured to perform the method 900. Additionally, or alternatively, one or more components of the memory device (e.g., the controller 130, the memory management component 225, temperature component 230, and/or charge pump control component 235) may perform or may be configured to perform the method 900. Thus, means for performing the method 900 may include the memory device and/or one or more components of the memory device. Additionally, or alternatively, a non-transitory computer-readable medium may store one or more instructions that, when executed by the memory device (e.g., the controller 130 of the memory device 120), cause the memory device to perform the method 900.

As shown in FIG. 9, the method 900 may include detecting a temperature associated with a memory device (block 910). As further shown in FIG. 9, the method 900 may include identifying a ramp rate value that corresponds to the temperature (block 920). As further shown in FIG. 9, the method 900 may include selectively configuring a ramp rate of a charge pump of the memory device based on the ramp rate value (block 930).

The method 900 may include additional aspects, such as any single aspect or any combination of aspects described below and/or described in connection with one or more other methods or operations described elsewhere herein.

In a first aspect, identifying the ramp rate value includes identifying the ramp rate value based on a quantity of bits associated with a memory cell.

In a second aspect, alone or in combination with the first aspect, the memory cell is an SLC.

In a third aspect, alone or in combination with one or more of the first and second aspects, identifying the ramp rate value includes identifying the ramp rate value using a lookup table.

In a fourth aspect, alone or in combination with one or more of the first through third aspects, the lookup table indicates multiple temperature ranges and, for each temperature range of the multiple temperature ranges, a corresponding ramp rate value.

Although FIG. 9 shows example blocks of a method 900, in some implementations, the method 900 may include additional blocks, fewer blocks, different blocks, or differently arranged blocks than those depicted in FIG. 9. Additionally, or alternatively, two or more of the blocks of the method 900 may be performed in parallel. The method 900 is an example of one method that may be performed by one or more devices described herein. These one or more devices may perform or may be configured to perform one or more other methods based on operations described herein.

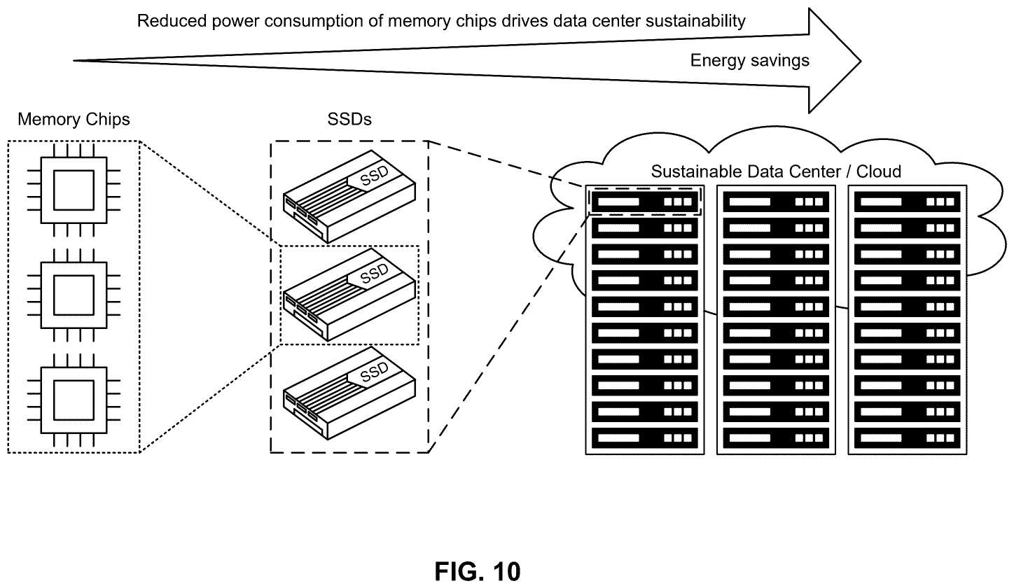

FIG. 10 is a diagram illustrating example systems in which the memory device 120 described herein may be used. In some implementations, one or more memory devices 120 may be included in a memory chip. Multiple memory chips may be packaged together and included in a higher level system, such as an SSD or another type of memory drive. Each SSD may include, for example, up to five memory chips, up to ten memory chips, or more. A data center or cloud computing environment may include multiple SSDs to store a large amount of data. For example, a data center may include hundreds, thousands, or more SSDs.

As described above, some implementations described herein reduce power consumption of a memory device 120. As shown in FIG. 10, this reduced power consumption drives data center sustainability and leads to energy savings because of the large volume of memory devices 120 included in a data center.

As indicated above, FIG. 10 is provided as an example. Other examples may differ from what is described with regard to FIG. 10.

In some implementations, a memory device includes one or more components configured to: receive a command to perform an operation; detect, responsive to receiving the command, a temperature associated with the memory device; and selectively configure, based on the temperature, a clock frequency of a charge pump of the memory device.

In some implementations, a method includes detecting a temperature associated with a memory device; identifying a ramp rate value that corresponds to the temperature; and selectively configure a ramp rate of a charge pump of the memory device based on the ramp rate value.

In some implementations, an apparatus includes means for receiving a command to perform an operation; means for detecting, responsive to receiving the command, a temperature associated with the apparatus; and means for selectively configuring, based on the temperature, a clock frequency of a charge pump of the apparatus.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of”' a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
receive a command to perform an operation;
detect, responsive to receiving the command, a temperature associated with the memory device; and
selectively configure, based on the temperature, a clock frequency of a charge pump of the memory device.

2. The memory device of claim 1, wherein the operation is a read operation.

3. The memory device of claim 2, wherein the one or more components, configured to selectively configure the clock frequency, are configured to selectively configure the clock frequency based on a quantity of bits associated with a memory cell.

4. The memory device of claim 3, wherein the memory cell is a single-level cell (SLC).

5. The memory device of claim 1, wherein the operation is a program operation.

6. The memory device of claim 1, wherein the one or more components, configured to selectively configure the clock frequency, are configured to selectively configure the clock frequency using a lookup table.

7. The memory device of claim 6, wherein the lookup table indicates multiple temperature ranges and, for each temperature range of the multiple temperature ranges, a corresponding clock frequency value.

8. The memory device of claim 1, wherein the one or more components are configured to:
perform the operation before detecting the temperature.

9. The memory device of claim 1, wherein the one or more components are configured to:
perform the operation after selectively configuring the clock frequency.

10. The memory device of claim 1, wherein the memory device is a non-volatile memory device.

11. The memory device of claim 10, wherein the non-volatile memory device is a NAND memory device.

12. A method, comprising:
detecting a temperature associated with a memory device;
identifying a ramp rate value that corresponds to the temperature; and
selectively configure a ramp rate of a charge pump of the memory device based on the ramp rate value.

13. The method of claim 12, wherein identifying the ramp rate value includes identifying the ramp rate value based on a quantity of bits associated with a memory cell.

14. The method of claim 13, wherein the memory cell is a single-level cell (SLC).

15. The method of claim 12, wherein identifying the ramp rate value includes identifying the ramp rate value using a lookup table.

16. The method of claim 15, wherein the lookup table indicates multiple temperature ranges and, for each temperature range of the multiple temperature ranges, a corresponding ramp rate value.

17. An apparatus, comprising:
means for receiving a command to perform an operation;
means for detecting, responsive to receiving the command, a temperature associated with the apparatus; and
means for selectively configuring, based on the temperature, a clock frequency of a charge pump of the apparatus.

18. The apparatus of claim 17, wherein the operation is a read operation.

19. The apparatus of claim 17, wherein the means for selectively configuring the clock frequency include means for selectively configuring the clock frequency using a lookup table.

20. The apparatus of claim 17, wherein the apparatus is a non-volatile memory device.
